(19) United States
(12) Patent Application Publication
(10) Pub. No.: US 2023/0144900 A1
(43) Pub. Date: May 11, 2023

(54) MULTI-FUNCTIONAL WIRELESS MODULE MONITORING SYSTEM IN A BATTERY MANAGEMENT SYSTEM

(71) Applicant: SENSATA TECHNOLOGIES, INC., ATTLEBORO, MA (US)

(72) Inventors: JING DENG, BELFAST (GB); STEPHEN C. MILLEN, COLERAINE (IE); JONATHAN M. RIGELSFORD, SHEFFIELD (GB)

(21) Appl. No.: 17/916,236

(22) PCT Filed: Apr. 29, 2021
(86) PCT No.: PCT/US2021/029912

§ 371 Date: Sep. 30, 2022

Related U.S. Application Data
(60) Provisional application No. 63/017,448, filed on Apr. 29, 2020.

(51) Int. Cl. G01R 31/36; G01R 31/392; G01R 31/396

(52) U.S. Cl. CPC G01R 31/3648; G01R 31/392; G01R 31/396

(57) ABSTRACT

Methods, apparatuses, and computer program products for utilizing a multi-functional wireless module monitoring system (MMS) in an electric battery pack are disclosed. In a particular embodiment, utilizing the multi-functional wireless MMS in an electric battery pack includes the multi-functional wireless MMS monitoring one or more attributes of a plurality of battery cells in the electric battery pack and generating based on the monitored one or more attributes, battery sensor data. Responsive to the multi-functional wireless MMS operating in a first operational mode, the multi-functional wireless MMS transmits via a wireless interface, a first set of the battery sensor data to a wireless network controller (WNC) of a battery management system (BMS). Responsive to the multi-functional wireless MMS operating in a second operational mode, the multi-functional wireless MMS transmits via a wired interface, a second set of the battery sensor data.

### BACKGROUND ART

Electric vehicles are powered by high voltage battery systems including multiple cells. Wireless battery management systems are used to monitor various attributes of the cells, including voltage, temperature, and current, in order to ensure proper and safe operation of the battery. In a conventional wired battery management system, multiple cells of the battery are grouped into modules, with each module having a component to monitor these attributes. Each of these components is wired to a central controller. Problems caused by this solution include lack of flexibility in pack design, wasted space due to connectors and cabling inside the battery pack, and increased challenges for battery second life usage.

### SUMMARY OF INVENTION

Methods, apparatuses, and computer program products for utilizing a multi-functional wireless module monitoring system (MMS) in an electric battery pack are disclosed. In a particular embodiment, utilizing the multi-functional wireless MMS in an electric battery pack includes the multi-functional wireless MMS monitoring one or more attributes of a plurality of battery cells in the electric battery pack and generating battery sensor data based on the monitored one or more attributes. Responsive to the multi-functional wireless MMS operating in a first operational mode, the multi-functional wireless MMS transmits a first set of the battery sensor data to a wireless network controller (WNC) of a battery management system (BMS) via a wireless interface. Responsive to the multi-functional wireless MMS operating in a second operational mode, the multi-functional wireless MMS transmits a second set of the battery sensor data via a wired interface.

The capability and functionality of a second operational mode in which the multi-functional wireless MMS is able to transmit the battery sensor data using a wired interface, allows the electric battery pack to be repurposed and reused in a second application that utilizes a wired interface for reporting the monitoring of the battery cells without having to replace the MMS. As will be further explained below, having the capability to repurpose and reuse the battery pack without replacing the MMS improves the performance and value of the electric battery pack and the MMS.

The foregoing and other objects, features and advantages of the invention will be apparent from the following more particular descriptions of exemplary embodiments of the invention as illustrated in the accompanying drawings wherein like reference numbers generally represent like parts of exemplary embodiments of the invention.

### BRIEF DESCRIPTION OF DRAWINGS

FIG. 1 sets forth a block diagram of a system for utilizing a multi-functional wireless module monitoring system (MMS) according to embodiments of the present disclosure;

FIG. 2A sets forth a block diagram of a multi-functional wireless MMS according to at least one embodiment of the present disclosure;

FIG. 2B sets forth a block diagram of a multi-functional wireless MMS according to at least one embodiment of the present disclosure;

FIG. 3 illustrates a block diagram of a wireless network controller for use with a multi-functional wireless MMS according to embodiments of the present disclosure;

FIG. 4 sets forth a flowchart to illustrate an implementation of a method for utilizing a multi-functional wireless MMS according to at least one embodiment of the present invention;

FIG. 5 sets forth a flowchart to illustrate an implementation of a method for utilizing a multi-functional wireless MMS according to at least one embodiment of the present invention;

FIG. 6 sets forth a flowchart to illustrate an implementation of a method for utilizing a multi-functional wireless MMS according to at least one embodiment of the present invention;

FIG. 7 sets forth a flowchart to illustrate an implementation of a method for utilizing a multi-functional wireless MMS according to at least one embodiment of the present invention;

FIG. 8 sets forth a flowchart to illustrate an implementation of a method for utilizing a multi-functional wireless MMS according to at least one embodiment of the present invention;

FIG. 9 sets forth a flowchart to illustrate an implementation of a method for utilizing a multi-functional wireless MMS according to at least one embodiment of the present invention; and

FIG. 10 sets forth a flowchart to illustrate an implementation of a method for utilizing a multi-functional wireless MMS according to at least one embodiment of the present invention.

### DESCRIPTION OF EMBODIMENTS

The terminology used herein for the purpose of describing particular examples is not intended to be limiting for further examples. Whenever a singular form such as “a”, “an” and “the” is used and using only a single element is neither explicitly or implicitly defined as being mandatory, further examples may also use plural elements to implement the same functionality. Likewise, when a functionality is subsequently described as being implemented using multiple elements, further examples may implement the same functionality using a single element or processing entity. It will be further understood that the terms “comprises”, “comprising”, “includes” and/or “including”, when used, specify the presence of the stated features, integers, steps, operations, processes, acts, elements and/or components, but do not preclude the presence or addition of one or more other features, integers, steps, operations, processes, acts, elements, components and/or any group thereof.

It will be understood that when an element is referred to as being “connected” or “coupled” to another element, the elements may be directly connected or coupled or via one or more intervening elements. If two elements A and B are combined using an “or”, this is to be understood to disclose all possible combinations, i.e., only A, only B, as well as A and B. An alternative wording for the same combinations is “at least one of A and B”. The same applies for combinations of more than two elements.

Accordingly, while further examples are capable of various modifications and alternative forms, some particular examples thereof are shown in the figures and will subsequently be described in detail. However, this detailed description does not limit further examples to the particular forms described. Further examples may cover all modifications, equivalents, and alternatives falling within the scope of the disclosure. Like numbers refer to like or similar elements throughout the description of the figures, which may be implemented identically or in modified form when compared to one another while providing for the same or a similar functionality.

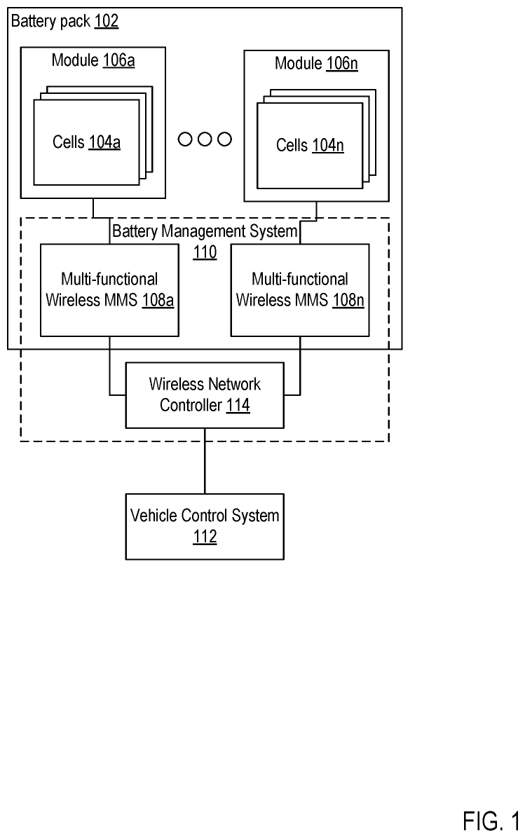

Exemplary methods, apparatuses, and computer program products for utilizing a multi-functional wireless module monitoring system (MMS) in a battery management system in accordance with the present invention are described with reference to the accompanying drawings, beginning with FIG. 1. FIG. 1 sets forth a diagram of a system for utilizing a multi-functional wireless MMS in a battery management system according to embodiments of the present disclosure. The system includes an electric battery pack (102), such as a high voltage battery for use in an electric vehicle. The battery pack (102) includes a plurality of cells (104a-n), such as Lithium-ion (Li-ion) cells. The cells (104a-n) are grouped into modules (106a-n) such that each module (106a-n) comprises a corresponding subset of the cells (104a-n). The cells (104a-n) may be physically grouped into modules (106a-n) using a casing, chassis, or other enclosure. The cells (104a-n) may also be logically grouped into modules (106a-n) by virtue of distinct groupings of cells (104a-n) being monitored by a distinct module monitoring system (108a-n), as will be described below.

The system also includes a battery management system (110). The battery management system (110) monitors various attributes of the cells (104a-n) and provides battery sensor data indicating these attributes to a vehicle control system (112). The battery management system (110) includes a plurality of multi-functional wireless module monitoring systems (hereafter, “MMS”) (108a-n). Each MMS (108a-n) is configured to monitor a corresponding module (106a-n) of cells (104a-n). For example, each module (106a-n) may have a MMS (108a-n) attached to a chassis, base, tray, or other mechanism holding the cells (104a-n) of the module (106a-n). Each MMS (108a-n) includes sensors to measure various attributes of the cells (104a-n) of its corresponding module (106a-n). Such attributes may include voltage, current, temperature, and potentially other attributes. The attributes are indicated in battery sensor data generated by the MMS (108a-n).

Each MMS (108a-n) is configured to operate in a first operational mode in which the MMS encodes its battery sensor data for transmission as a wireless signal and transmits its battery sensor data to a wireless network controller (WNC) (114) (e.g., via a 2.4 Ghz wireless channel). In some embodiments, the WNC (114) then sends the battery sensor data received from the MMSs (108a-n) to a vehicle control system (VCS) (112) using a wired or wireless communications channel. The VCS (112) may include a central “computer” of a vehicle. The VCS (112) may be a central control unit or may refer collectively to one or more vehicle subsystems.

The modules (106a-n) of an electric vehicle battery pack (102) are frequently reused in other electrically powered devices, such as electric bikes, scooters, battery back-up systems (UPS), caravan/boat, as well as hybrid vehicles. For example, assuming that the cells (104a-n) in a given module (106a-n) each total 48 volts, a single module (106a) may be repurposed in a 48 volt battery system. Such repurposed battery systems may recover energy through re-generative braking, and support power to motors to drive the vehicle, or power 12 V accessories DC/DC converter. Typically, reusing a module (106a-n) would require testing and validation of the module (106a-n) condition and existing module monitoring circuits (e.g., MMSs (108a-n)) would need to be replaced with an appropriate low voltage battery management system (BMS) (e.g., a “mini-BMS”).

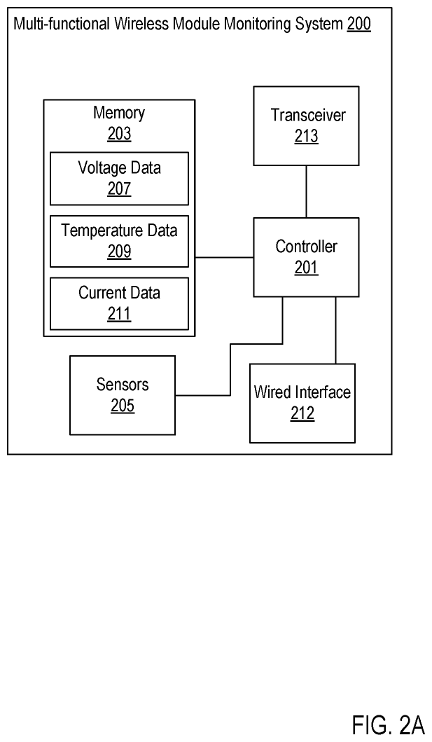

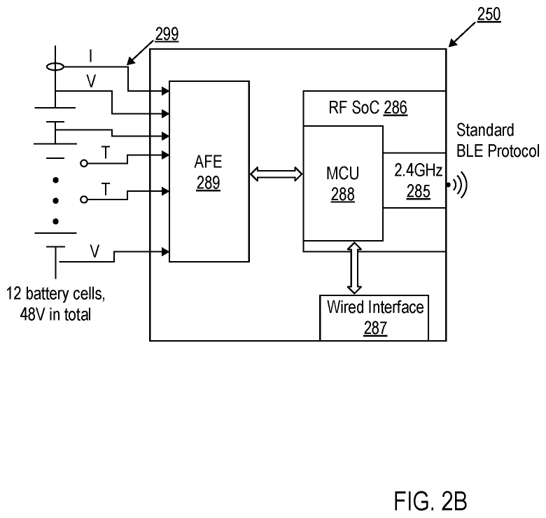

In the example of FIG. 1, the multi-functional wireless MMS may be configured to operate in a second operational mode in which the MMS functions as mini-BMS. The multi-functional wireless MMS (108a-n) share many features with a mini-BMS in the major hardware blocks. For example, the multi-functional wireless module monitoring circuits and a mini-BMS may both include a Radio Frequency System on a Chip (RF SoC) including an Analog Front End (AFE) and Micro-control Unit (MCU). To facilitate the reuse of a module (106a-n) of an electric vehicle battery pack (102) in another battery system, each MMS (108a-n) may also include current-sensing capabilities and a wired interface, such as in the MMS (200) of FIG. 2A and MMS (250) of FIG. 2B.

For further explanation, FIG. 2A sets forth a block diagram of a multi-functional wireless module monitoring system (MMS) (200) (e.g, a multi-functional wireless module monitoring system (108a-n) of FIG. 1) for use in a wireless sensor network having a secure wireless protocol according to embodiments of the present disclosure. The MMS (200) includes a controller (201) coupled to a memory (203). The controller (201) is configured to obtain sensor readings from sensors (205) (e.g., voltage sensors, temperature sensors, current sensors) to generate battery sensor data (e.g., voltage data (207), temperature data (209), current data (210). The controller (201) may include or implement a microcontroller, an Application Specific Integrated Circuit (ASIC), a digital signal processor (DSP), a programmable logic array (PLA) such as a field programmable gate array (FPGA), or other data computation unit in accordance with the present disclosure. The battery sensor data (e.g., voltage data (207), temperature data (209), current data (211)) may be stored in the memory (203). The memory (203) may be a non-volatile memory such as flash memory.

The sensors (205) are configured to measure attributes (e.g., voltage, temperature, current) of cells of a module (e.g., cells (104a-n) of a module (106a-n)) on which the MMS (200) is installed. In the example of FIG. 2A, the MMS (200) includes a transceiver or wireless interface (213) and a wired interface (212) coupled to the controller (201). In a particular embodiment, responsive to the MMS (200) operating in a first operational mode, the MMS (200) uses the transceiver to transmit battery sensor data to a wireless network controller (WNC) of a battery management system (BMS) and responsive to the MMS (200) operating in a second operational mode, the MMS (200) may use the wired interface to transmit the battery sensor data.

In the example of FIG. 2B, the MMS (250) may include current-sensing capabilities via a hall or Shunt sensor (299) and connect to either a general purpose input/output (GPIO) pen of an AFE (289) or dedicating current sensing input of the AFE. The wired interface (287) may be coupled to the MCU (288) of the RF SoC (286). The wired interface may include outputs such as a charge enable/disable signal, a discharge enable/disable signal, a state of charge indicator through an analog signal of a predefined range (e.g., of 0-5 V or 4-20 mA) corresponding to 0-100 percent, a charge/discharge current limit indicator through an analog signal range (e.g., of 0-5 V or 4-20 mA), and/or a power supply.

One or more modules implemented on the MMS (250) (e.g., software modules executed on the RF SoC, software modules executed on the MCU of the RF SoC, dedicated logic on the RF SoC) may facilitate switching between a first operational mode (e.g., an MMS mode) and a second operational mode (e.g., a BMS mode). The MMS mode allows the MMS (250) to perform operations associated with an MMS (108a-n) for monitoring one of a plurality of modules (106a-n) in a battery pack (102). The BMS mode allows the MMS (250) to perform operations for monitoring a repurposed module (106a-n) in a battery system powered by the single repurposed module (106a-n). For example, when in MMS mode, the MMS (250) may be configured to communicate using a wireless interface (e.g., a 2.4 GHz interface (285)) to a WNC (114) using a first protocol (e.g., a proprietary protocol), and the wired interffice may not be used or coupled to other components. When in BMS mode, the wireless interface may instead use a second protocol such as a Bluetooth low energy (BLE) protocol, and use the wired interface for reporting the monitored attributes. For example, the use of the BILE protocol allows for monitoring battery condition using mobile devices. Other service applications may also be performed using the BLE protocol. Additionally, the MMS (250) may store historical and health information for a corresponding monitored module (106a-n) during use in a battery pack (102). Such historical and health information may be used to grade, evaluate, or otherwise determine the status of the module (106a-n) for repurposing in another battery system.

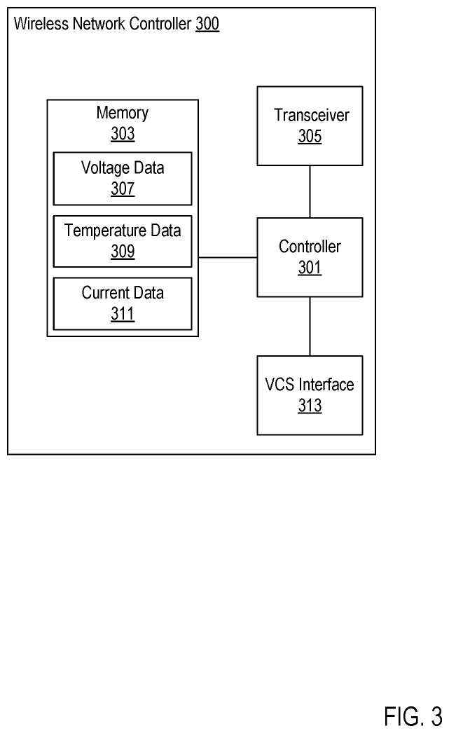

For further explanation, FIG. 3 sets forth a block diagram of a wireless network controller (WNC) (300) (e.g., a wireless network controller (114) of FIG. 1) for use with a multi-functional wireless MMS according to embodiments of the present disclosure. The WNC (300) includes a controller (301) coupled to a memory (303). The controller (301) is configured to request and receive, via a transceiver (305) from a plurality of MMSs, sensor data (e.g., voltage data (307), temperature data (309), current data (311)). The controller (301) may include or implement a microcontroller, an Application Specific Integrated Circuit (ASIC), a digital signal processor (DSP), a programmable logic array (PLA) such as a field programmable gate array (FPGA), or other data computation unit in accordance with the present disclosure. The battery sensor data (e.g., voltage data (307), temperature data (309), current data (311)) may be stored in the memory (303). The memory (303) may be a non-volatile memory such as flash memory. The controller (301) is further configured to provide formatted battery sensor data to a BMS controller or a vehicle control system (e.g., a VCS (112) of FIG. 1) via an interface (313). The interface may include a bus or other wired connection to a BMS controller or VCS.

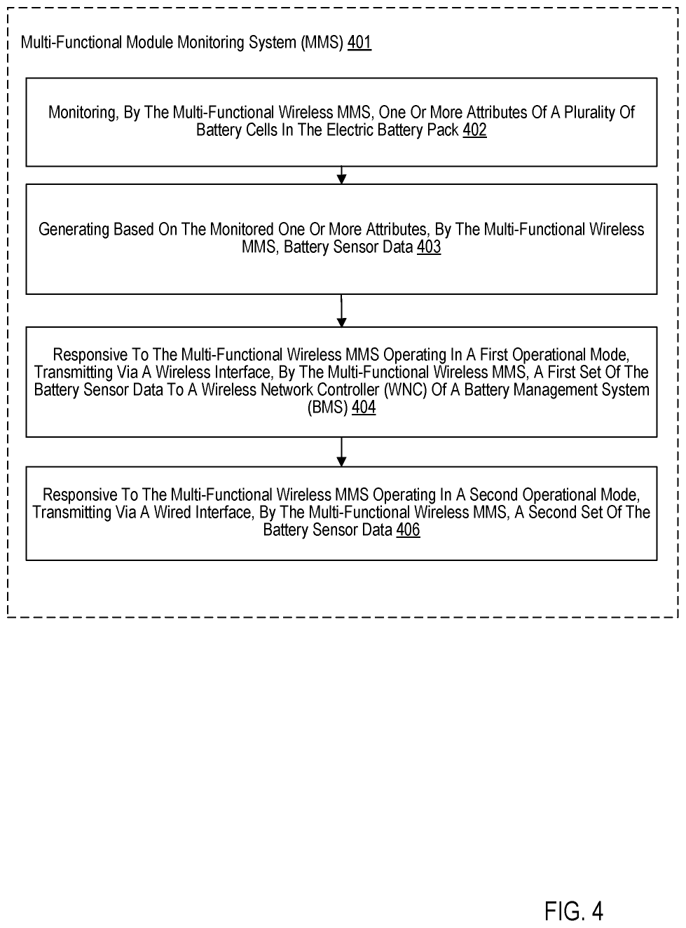

For further explanation, FIG. 4 sets forth a flowchart to illustrate an implementation of a method for utilizing a multi-functional wireless MMS according to at least one embodiment of the present invention. The method of FIG. 4 includes monitoring (402), by the multi-functional wireless MMS (401), one or more attributes of a plurality of battery cells in the electric battery pack. A multi-functional wireless MMS may be the MMS (108a-n) of FIG. 1, the MMS (200) of FIG. 2A, the MMS (250) of FIG. 2B. Monitoring (402), by the multi-functional wireless MMS (401), one or more attributes of a plurality of battery cells in the electric battery pack may be carried out by using sensors to measure voltage, temperature, current in the plurality of battery cells.

The method of FIG. 4 also includes generating (403) based on the monitored one or more attributes, by the multi-functional wireless MMS (401), battery sensor data. Generating (403) based on the monitored one or more attributes, by the multi-functional wireless MMS (401), battery sensor data may be carried out by generating voltage data, temperature data, and current data.

The method of FIG. 4 also includes responsive to the multi-functional wireless MMS operating in a first operational mode, transmitting (404) via a wireless interface, by the multi-functional wireless MMS (401), a first set of the battery sensor data to a wireless network controller (WNC) of a battery management system (BMS). Transmitting (404) via a wireless interface, by the multi-functional wireless MMS (401), a first set of the battery sensor data to a wireless network controller (WNC) of a battery management system (BMS) may be carried out by transmitting some or all of the battery sensor data to the WNC.

In addition, the method of FIG. 4 also includes responsive to the multi-functional wireless MMS operating in a second operational mode, transmitting (406) via a wired interface, by the multi-functional wireless MMS (401), a second set of the battery sensor data. Transmitting (406) via a wired interface, by the multi-functional wireless MMS (401), a second set of the battery sensor data may be carried out by transmitting some or all the battery sensor data to an external device that is coupled to the wired interface. In a particular embodiment, the first set of battery sensor data is the same as the second set of battery sensor data.

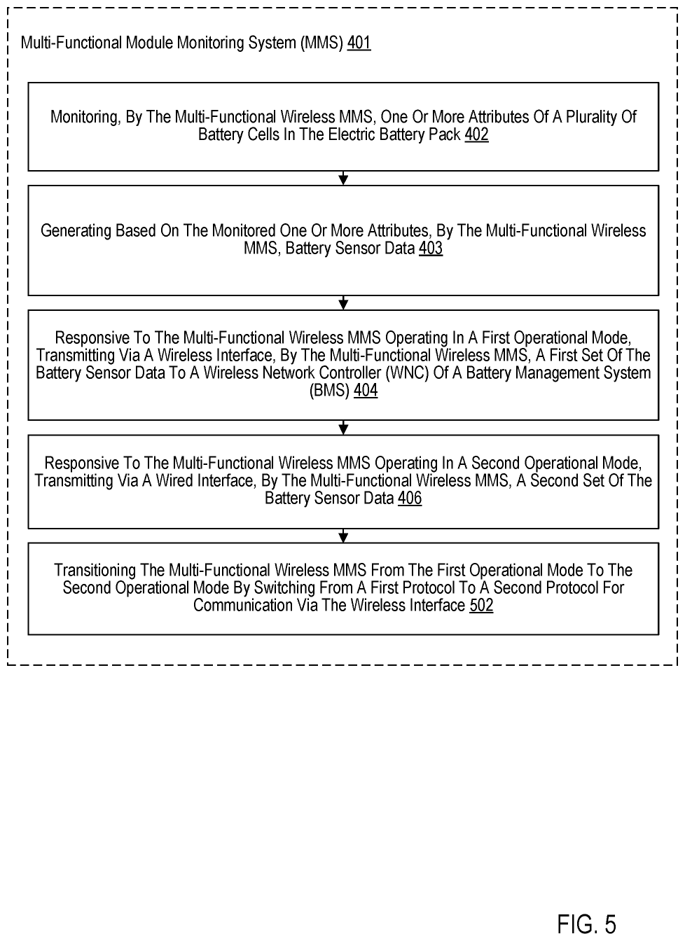

For further explanation, FIG. 5 sets forth a flowchart to illustrate an implementation of a method for utilizing a multi-functional wireless MMS according to at least one embodiment of the present invention. The method of FIG. 5 is similar to the method of FIG. 4 in that the method of FIG. 5 also includes monitoring (402), by the multi-functional wireless MMS (401), one or more attributes of a plurality of battery cells in the electric battery pack; generating (403) based on the monitored one or more attributes, by the multi-functional wireless MMS (401), battery sensor data; responsive to the multi-functional wireless MMS operating in a first operational mode, transmitting (404) via a wireless interface, by the multi-functional wireless MMS (401), a first set of the batter sensor data to a wireless network controller (WNC) of a battery management system (BMS); and responsive to the multi-functional wireless MMS operating in a second operational mode, transmitting (406) via a wired interface, by the multi-functional wireless MMS (401), a second set of the battery sensor data.

The method of FIG. 5 includes transitioning (502) the multi-functional wireless MMS from the first operational mode to the second operational mode by switching from a first protocol to a second protocol for communication via the wireless interface. Transitioning (502) the multi-functional wireless MMS from the first operational mode to the second operational mode by switching from a first protocol to a second protocol for communication via the wireless interface may be carried out by implementing the second protocol for transmitting and receiving messages using the wireless interffice. For example, the MMS may switch to Bluetooth low energy (BLE) in the second operational mode. This second protocol may allow the MMS to communicate with a mobile device to perform monitoring or service operations. For example, in a particular embodiment, a user may wirelessly connect a mobile device to the MMS and request that the MMS transmit data to the mobile device,

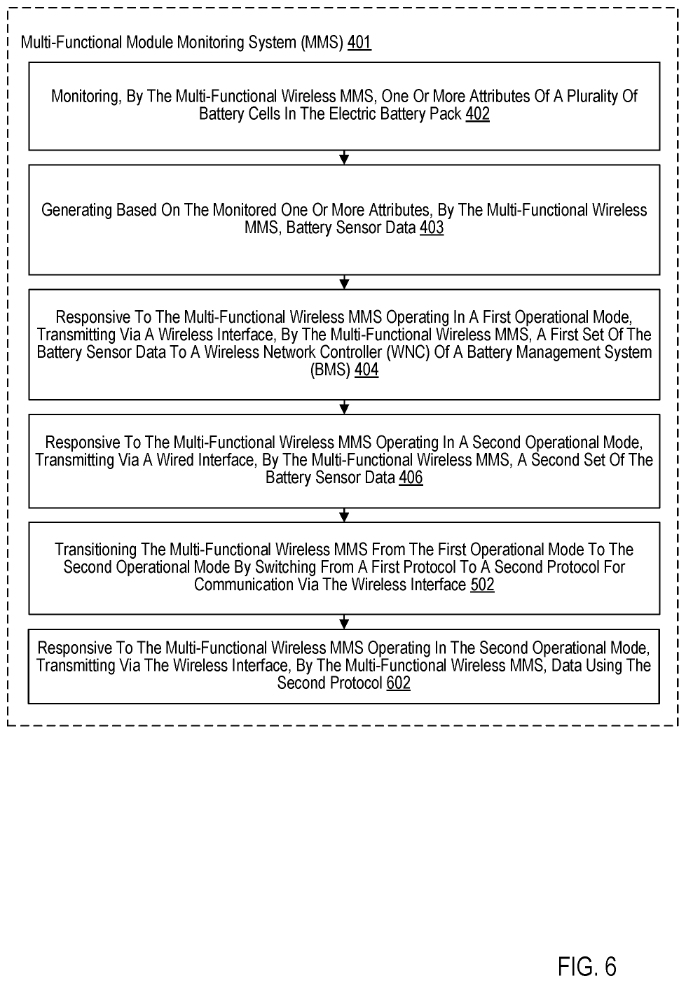

For further explanation, FIG. 6 sets forth a flowchart to illustrate an implementation of a method for utilizing a multi-functional wireless MMS according to at least one embodiment of the present invention. The method of FIG. 6 is similar to the method of FIG. 5 in that the method of FIG. 6 also includes monitoring (402), by the multi-functional wireless MMS (401), one or more attributes of a plurality of battery cells in the electric battery pack; generating (403) based on the monitored one or more attributes, by the multi-functional wireless MMS (401), battery sensor data; responsive to the multi-functional wireless MMS operating in a first operational mode, transmitting (404) via a wireless interface, by the multi-functional wireless MMS (401), a first set of the battery sensor data to a wireless network controller (WNC) of a battery management system (BMS); responsive to the multi-functional wireless MMS operating in a second operational mode, transmitting (406) via a wired interface, by the multi-functional wireless MMS (401), a second set of the battery sensor data; and transitioning (502) the multi-functional wireless MMS from the first operational mode to the second operational mode by switching from a first protocol to a second protocol for communication via the wireless interface.

The method of FIG. 6 also includes responsive to the multi-functional wireless MMS operating in the second operational mode, transmitting (602) via the wireless interface, by the multi-functional wireless MMS (401), data using the second protocol. Transmitting (602) via the wireless interface, by the multi-functional wireless MMS (401), data using the second protocol may be carried out by transmitting messages to an external wireless device, such as a mobile device.

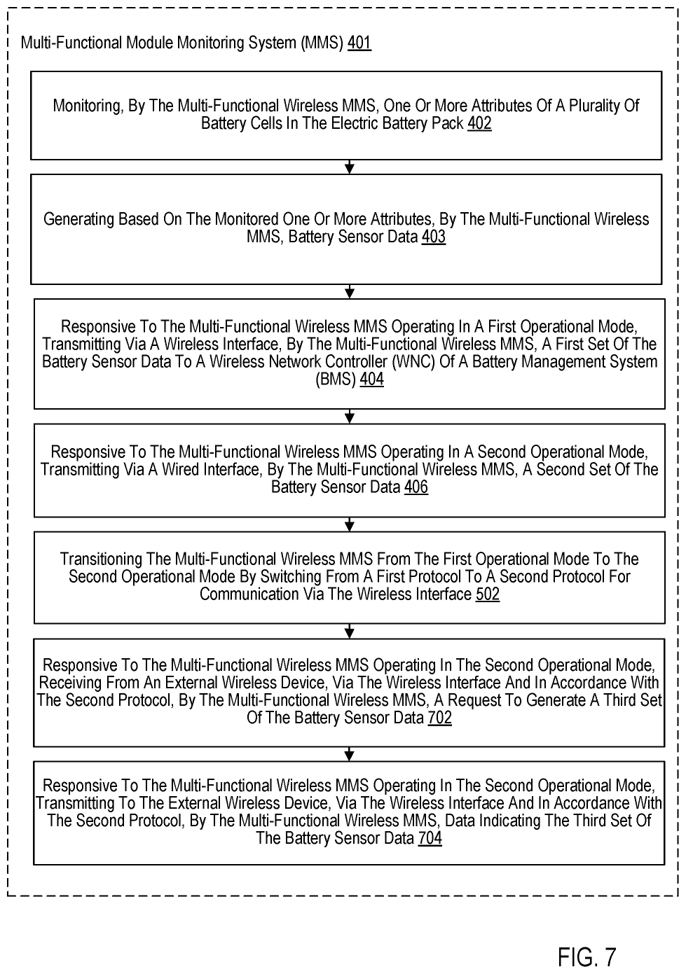

For further explanation, FIG. 7 sets forth a flowchart to illustrate an implementation of a method for utilizing a multi-fimctional wireless MMS according to at least one embodiment of the present invention. The method of FIG. 7 is similar to the method of FIG. 5 in that the method of FIG. 7 also includes monitoring (402), by the multi-functional wireless MMS (401), one or more attributes of a plurality of battery cells in the electric battery pack; generating (403) based on the monitored one or more attributes, by the multi-functional wireless MMS (401), battery sensor data; responsive to the multi-functional wireless MMS operating in a first operational mode, transmitting (404) via a wireless interface, by the multi-functional wireless MMS (401), a first set of the battery sensor data to a wireless network controller (WNC) of a battery management system (BMS); responsive to the multi-functional wireless MMS operating in a second operational mode, transmitting (406) via a wired interface, by the multi-functional wireless MMS (401), a second set of the battery sensor data; and transitioning (502) the multi-functional wireless MMS from the first operational mode to the second operational mode by switching from a first protocol to a second protocol for communication via the wireless interface.

The method of FIG. 7 also includes responsive to the multi-functional wireless MMS operating in the second operational mode, receiving (702) from an external wireless device, via the wireless interface and in accordance with the second protocol, by the multi-functional wireless MMS (401), a request to generate a third set of the battery sensor data. Receiving (702.) from an external wireless device, via the wireless interface and in accordance with the second protocol, by the multi-functional wireless MMS (401), a request to generate a third set of the battery sensor data may be carried out by receiving a message that indicates particular attributes to be monitored; receiving a request to perform a particular monitoring procedure; receiving a request for health information; and receiving a request for a status or grade of the plurality of battery cells.

In addition, the method of FIG. 7 includes responsive to the multi-functional wireless MMS operating in the second operational mode, transmitting (704) to the external wireless device, via the wireless interface and in accordance with the second protocol, by the multi-functional wireless MMS (401), data indicating the third set of the battery sensor data. Transmitting (704) to the external wireless device, via the wireless interface and in accordance with the second protocol, by the multi-functional wireless MMS (401), data indicating the third set of the battery sensor data may be carried out by transmitting the third set of battery sensor data using the wireless interface.

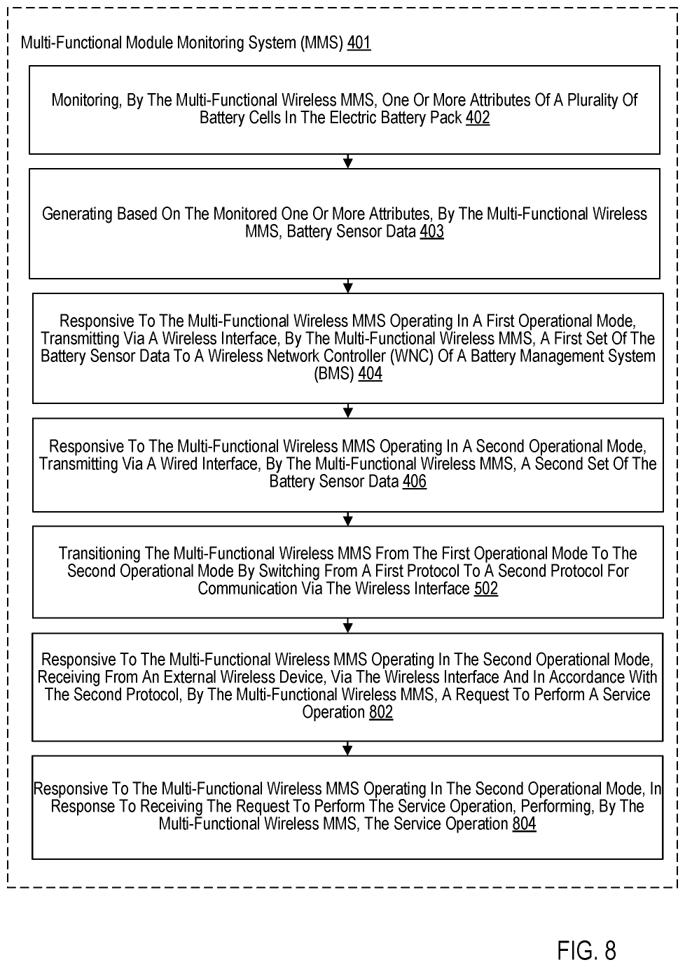

For further explanation, FIG. 8 sets forth a flowchart to illustrate an implementation of a method for utilizing a multi-functional wireless MMS according to at least one embodiment of the present invention. The method of FIG. 8 is similar to the method of FIG. 5 in that the method of FIG. 8 also includes monitoring (402), by the multi-functional wireless MMS (401), one or more attributes of a plurality of battery cells in the electric battery pack; generating (403) based on the monitored one or more attributes, by the multi-functional wireless MMS (401), battery sensor data; responsive to the multi-functional wireless MMS operating in a first operational mode, transmitting (404) via a wireless interface, by the multi-functional wireless MMS (401), a first set of the battery sensor data to a wireless network controller (WNC) of a battery management system (BMS); responsive to the multi-functional wireless MMS operating in a second operational mode, transmitting (406) via a wired interface, by the multi-functional wireless MMS (401), a second set of the battery sensor data; and transitioning (502) the multi-functional wireless MMS from the first operational mode to the second operational mode by switching from a first protocol to a second protocol for communication via the wireless interface.

The method of FIG. 8 includes responsive to the multi-functional wireless MMS operating in the second operational mode, receiving (802) from an external wireless device, via the wireless interface and in accordance with the second protocol, by the multi-functional wireless MMS (401), a request to perform a service operation. A service operation may be an operation that the MMS performs to monitor, check, or service the plurality of battery cells. Receiving (802) from an external wireless device, via the wireless interface and in accordance with the second protocol, by the multi-functional wireless MMS (401), a request to perform a service operation may be carried out by receiving a message to monitor, check, or service the plurality of battery cells.

In addition, the method of FIG. 8 includes responsive to the multi-functional wireless MMS operating in the second operational mode, in response to receiving the request to perform the service operation, performing (804), by the multi-functional wireless MMS (401), the service operation. Performing (804), by the multi-functional wireless MMS (401), the service operation may he carried out by executing the service operation.

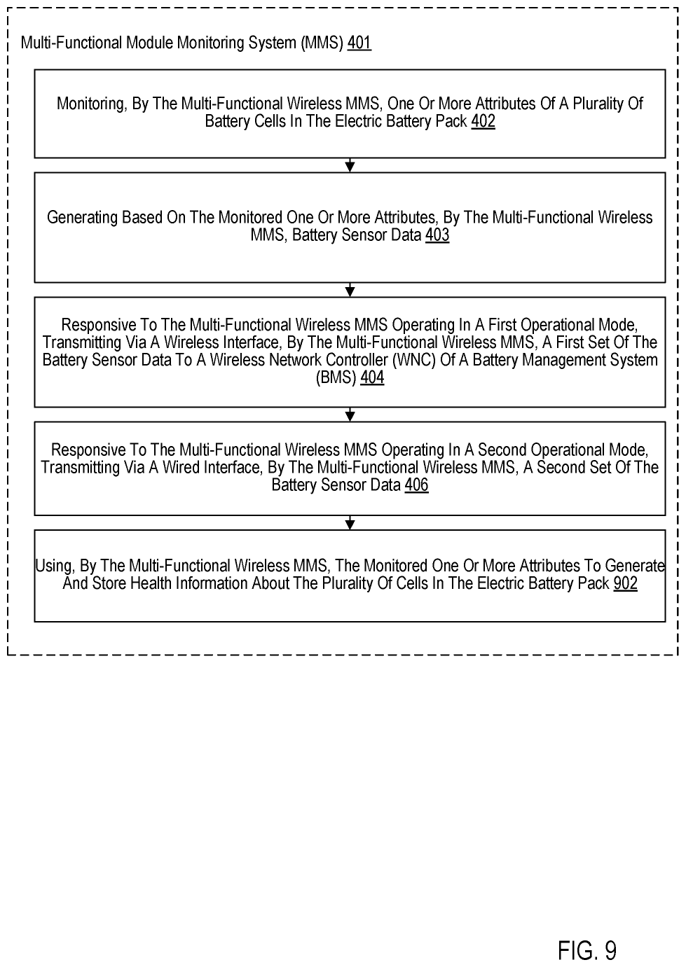

For further explanation, FIG. 9 sets forth a flowchart to illustrate an implementation of a method for utilizing a multi-functional wireless MMS according to at least one embodiment of the present invention. The method of FIG. 9 is similar to the method of FIG. 4 in that the method of FIG. 9 also includes monitoring (402), by the multi-functional wireless MMS (401), one or more attributes of a plurality of battery cells in the electric battery pack; generating (403) based on the monitored one or more attributes, by the multi-functional wireless MMS (401), battery sensor data; responsive to the multi-functional wireless MMS operating in a first operational mode, transmitting (404) via a wireless interface, by the multi-functional wireless MMS (401), a first set of the battery sensor data to a wireless network controller (WNC) of a battery management system (BMS); and responsive to the multi-functional wireless MMS operating in a second operational mode, transmitting (406) via a wired interface, by the multi-functional wireless MMS (401), a second set of the battery sensor data.

The method of FIG. 9 includes using (902), by the multi-functional wireless MMS (401), the monitored one or more attributes to generate and store health information about the plurality of cells in the electric battery pack. Health inthrmation may be information that is based on the monitored attributes and indicates the health or status of the plurality of battery cells. For example, the health information may include the battery sensor data and may include data that is generated by analyzing data from the plurality of battery cells including battery sensor data. Using (902), by the multi-functional wireless MMS (401), the monitored one or more attributes to generate and store health information about the plurality of cells in the electric battery pack may be carried out by storing the battery sensor data as health information; analyzing the battery sensor data to generate the health information; and analyzing other data associated with the plurality of battery cells to generate the health information.

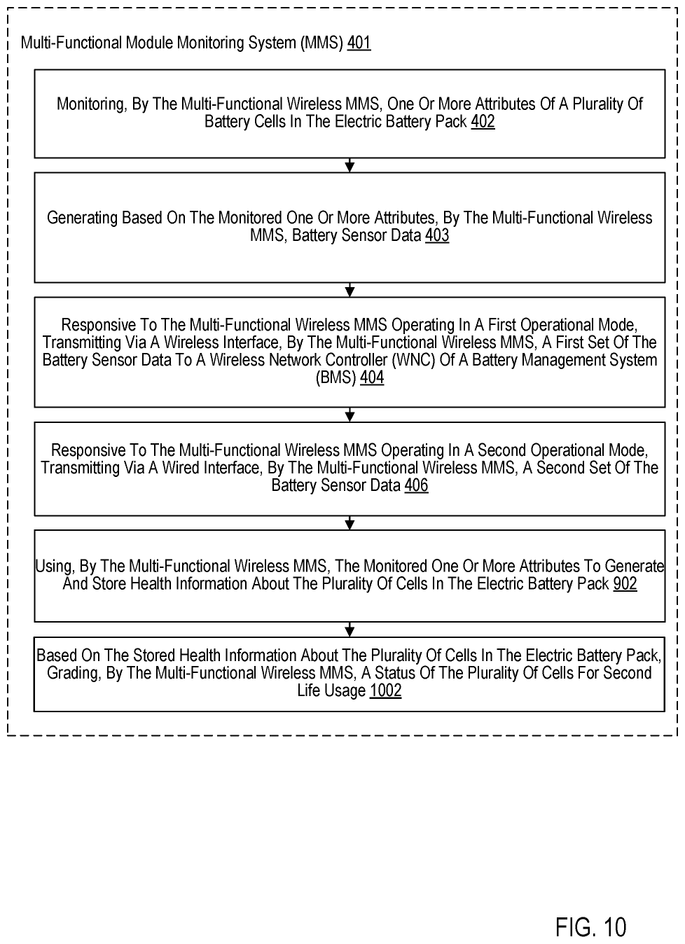

For further explanation, FIG. 10 sets forth a flowchart to illustrate an implementation of a method for utilizing a multi-functional wireless MMS according to at least one embodiment of the present invention. The method of FIG. 10 is similar to the method of FIG. 9 in that the method of FIG. 10 also includes monitoring (402), by the multi-functional wireless MMS (401), one or more attributes of a plurality of battery cells in the electric battery pack; generating (403) based on the monitored one or more attributes, by the multi-functional wireless MMS (401), battery sensor data; responsive to the multi-functional wireless MMS operating in a first operational mode, transmitting (404) via a wireless interface, by the multi-functional wireless MMS (401), a first set of the battery sensor data to a wireless network controller (WNC) of a battery management system (BMS); responsive to the multi-functional wireless MMS operating in a second operational mode, transmitting (406) via a wired interface, by the multi-functional wireless MMS (401), a second set of the battery sensor data; and using (902), by the multi-functional wireless MMS (401), the monitored one or more attributes to generate and store health information about the plurality of cells in the electric battery pack.

The method of FIG. 10 includes based on the stored health information about the plurality of cells in the electric battery pack, determining (1002), by the multi-functional wireless MMS (401), a status of the plurality of cells fur second life usage. Determining (1002), by the multi-functional wireless MMS (401), a status of the plurality of cells for second life usage may be carried out by comparing one or more values in the health information to one or more thresholds associated with a grading standard; based on the results of the comparison, determining one or more statuses of the plurality of battery cells. For example, when a module of an electric battery pack is being repurposed, the condition of the module may need to be tested and validated. In this example, the multi-functional wireless MMS may use the health information to perform this testing and evaluation and report the results to another device via the wireless interface.

In view of the explanations set forth above, readers will recognize that the benefits of a multi-functional wireless module monitoring system in an electric vehicle battery pack according to embodiments of the present disclosure include, but are not limited to:
Improved performance of a module monitoring system by allowing for modules of an electric vehicle battery pack to be reused or repurposed without needing to replace the installed module monitoring systems.
Improved performance of a module monitoring system by allowing for the health of potentially repurposed modules to be evaluated using historical information for the module during its use in the electric vehicle battery pack.

Exemplary embodiments of the present invention are described largely in the context of a fully functional computer system for lifetime battery tracking using a wireless interlace. Readers of skill in the art will recognize, however, that the present invention also may be embodied in a computer program product disposed upon computer readable storage media for use with any suitable data processing system. Such computer readable storage media may be any storage medium for machine-readable information, including magnetic media, optical media, or other suitable media. Examples of such media include magnetic disks in hard. drives or diskettes, compact disks for optical drives, magnetic tape, and others as will occur to those of skill in the art. Persons skilled in the art will immediately recognize that any computer system having suitable programming means will be capable of executing the steps of the method of the invention as embodied in a computer program product. Persons skilled in the art will recognize also that, although some of the exemplary embodiments described in this specification are oriented to software installed and executing on computer hardware, nevertheless, alternative embodiments implemented as firmware or as hardware are well within the scope of the present invention.

The present invention may be a system, an apparatus, a method, and/or a computer program product. The computer program product may include a computer readable storage medium (or media) having computer readable program instructions thereon for causing a processor to carry out aspects of the present invention.

The computer readable storage medium can be a tangible device that can retain and store instructions for use by an instruction execution device. The computer readable storage medium may be, for example, but is not limited to, an electronic storage device, a magnetic storage device, an optical storage device, an electromagnetic storage device, a semiconductor storage device, or any suitable combination of the foregoing. A non-exhaustive list of more specific examples of the computer readable storage medium includes the following: a portable computer diskette, a hard disk, a random access memory (RAM), a read-only memory (ROM), an erasable programmable read-only memory (EPROM or Flash memory), a static random access memory (SRAM), a portable compact disc read-only memory (CD-ROM), a digital versatile disk (DVI)), a memory stick, a floppy disk, a mechanically encoded device such as punch-cards or raised structures in a groove having instructions recorded thereon, and any suitable combination of the foregoing. A computer readable storage medium, as used herein, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire.

Computer readable program instructions described herein can be downloaded to respective computing/processing devices from a computer readable storage medium or to an external computer or external storage device via a network, for example, the Internet, a local area network, a wide area network and/or a wireless network. The network may comprise copper transmission cables, optical transmission fibers, wireless transmission, routers, firewalls, switches, gateway computers and/or edge servers. A network adapter card or network interface in each computing/processing device receives computer readable program instructions from the network and forwards the computer readable program instructions for storage in a computer readable storage medium within the respective computing/processing device.

Computer readable program instructions for carrying out operations of the present invention may be assembler instructions, instruction-set-architecture (ISA) instructions, machine instructions, machine dependent instructions, microcode, firmware instructions, state-setting data, or either source code or object code written in any combination of one or more programming languages, including an object oriented programming language such as Smalltalk, C++ or the like, and conventional procedural programming languages, such as the “C” programming language or similar programming languages. The computer readable program instructions may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider). In some embodiments, electronic circuitry including, for example, programmable logic circuitry, field-programmable gate arrays (FPGA), or programmable logic arrays (PLA) may execute the computer readable program instructions by utilizing state information of the computer readable program instructions to personalize the electronic circuitry, in order to perform aspects of the present invention.

Aspects of the present invention are described herein with reference to flowchart illustrations and/or block diagrams of methods, apparatus (systems), and computer program products according to embodiments of the invention. It will be understood that each block of the flowchart illustrations and/or block diagrams, and combinations of blocks in the flowchart illustrations and/or block diagrams, can be implemented by computer readable program instructions.

These computer readable program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks. These computer readable program instructions may also be stored in a computer readable storage medium that can direct a computer, a programmable data processing apparatus, and/or other devices to function in a particular manner, such that the computer readable storage medium having instructions stored therein comprises an article of manufacture including instructions which implement aspects of the function/act specified in the flowchart and/or block diagram block or blocks.

The computer readable program instructions may also be loaded onto a computer, other programmable data processing apparatus, or other device to cause a series of operational steps to be performed on the computer, other programmable apparatus or other device to produce a computer implemented process, such that the instructions which execute on the computer, other programmable apparatus, or other device implement the functions/acts specified in the flowchart and/or block diagram block or blocks.

The flowchart and block diagrams in the Figures illustrate the architecture, functionality, and operation of possible implementations of systems, methods, and computer program products according to various embodiments of the present invention. In this regard, each block in the flowchart or block diagrams may represent a module, segment, or portion of instructions, which comprises one or more executable instructions for implementing the specified logical function(s). In some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

Advantages and features of the present disclosure can be further described by the following statements:

1. A method for utilizing a multi-functional wireless module monitoring system (MMS) in an electric battery pack, the method comprising: monitoring, by the multi-functional wireless MMS, one or more attributes of a plurality of battery cells in the electric battery pack; generating based on the monitored one or more attributes, by the multi-functional wireless MMS, battery sensor data; responsive to the multi-functional wireless MMS operating in a first operational mode, transmitting via a wireless interface, by the multi-functional wireless MMS, a first set of the battery sensor data to a wireless network controller (WNC) of a battery management system (BMS); and responsive to the multi-functional wireless MMS operating in a second operational mode, transmitting via a wired interface, by the multi-functional wireless MMS, a second set of the battery sensor data.

2. The method of statement 1, further comprising transitioning the multi-functional wireless MMS from the first operational mode to the second operational mode by switching from a first protocol to a second protocol for communication via the wireless interface.

3. The method of statement 1 or 2, further comprising responsive to the multi-functional wireless MMS operating in the second operational mode, transmitting via the wireless interface, by the multi-functional wireless MMS, data using the second protocol.

4. The method of any of statements 1-3 further comprising: responsive to the multi-functional wireless MMS operating in the second operational mode: receiving from an external wireless device, via the wireless interface and in accordance with the second protocol, by the multi-functional wireless MMS, a request to generate a third set of the battery sensor data based on the one or more attributes; and transmitting to the external wireless device, via the wireless interface and in accordance with the second protocol, by the multi-functional wireless MMS, the third set of the battery sensor data.

5. The method of any of statements 1-4 further comprising: responsive to the multi-functional wireless MMS operating in the second operational mode: receiving from an external wireless device, via the wireless interface and in accordance with the second protocol, by the multi-functional wireless MMS, a request to perform a service operation; and in response to receiving the request to perform the service operation, performing, by the multi-functional wireless MMS, the service operation.

6. The method of any of statements 1-5 further comprising using, by the multi-functional wireless MMS, the monitored one or more attributes to generate and store health information about the plurality of cells in the electric battery pack.

7. The method of any of statements 1-6 further comprising based on the stored health information about the plurality of cells in the electric battery pack, determining, by the multi-functional wireless MMS, a status of the plurality of cells for second life usage.

8. The method of any of statements 1-7, wherein the second protocol comprises a Bluetooth Low Energy (BLE) protocol.

9. The method of any of statements 1-8 wherein the MMS includes a sensor for sensing current associated with the plurality of battery cells.

10. An apparatus including a processor and memory coupled to the processor, the memory including computer program instructions that when executed by the processor cause the apparatus to carry out the operations of: monitoring, by the multi-functional wireless MMS, one or more attributes of a plurality of battery cells in the electric battery pack: generating based on the monitored one or more attributes, by the multi-functional wireless MMS, battery sensor data; responsive to the multi-functional wireless MMS operating in a first operational mode, transmitting via a wireless interface, by the multi-functional wireless MMS, a first set of the battery sensor data to a wireless network controller (MNC) of a battery management system (BMS); and responsive to the multi-functional wireless MMS operating in a second operational mode, transmitting via a wired interface, by the multi-functional wireless MMS, a second set of the battery sensor data.

11. The apparatus of statement 10, wherein the memory further includes computer program instructions that when executed by the processor cause the apparatus to carry out the operations of: transitioning the multi-functional wireless MMS from the first operational mode to the second operational mode by switching from a first protocol to a second protocol for communication via the wireless interface.

12. The apparatus of statements 10 or 11, wherein the memory further includes computer program instructions that when executed by the processor cause the apparatus to carry out the operations of: responsive to the multi-functional wireless MMS operating in the second operational mode, transmitting via the wireless interface, by the multi-functional wireless MMS, data using the second protocol.

13. The apparatus of any of statements 10-12, wherein the memory further includes computer program instructions that when executed by the processor cause the apparatus to carry out the operations of responsive to the multi-functional wireless MMS operating in the second operational mode: receiving from an external wireless device, via the wireless interface and in accordance with the second protocol, by the multi-functional wireless MMS, a request to generate a third set of the battery sensor data based on the one or more attributes; and transmitting to the external wireless device, via the wireless interface and in accordance with the second protocol, by the multi-functional wireless MMS, the third set of the battery sensor data.

14. The apparatus of any of statements 10-13, wherein the memory further includes computer program instructions that when executed by the processor cause the apparatus to carry out the operations of: responsive to the multi-functional wireless MMS operating in the second operational mode: receiving from an external wireless device, via the wireless interface and in accordance with the second protocol, by the multi-functional wireless MMS, a request to perform a service operation; and in response to receiving the request to perform the service operation, performing, by the multi-functional wireless MMS, the service operation.

15. The apparatus of any of statements 10-14, wherein the memory further includes computer program instructions that when executed by the processor cause the apparatus to carry out the operations of: using, by the multi-functional wireless MMS, the monitored one or more attributes to generate and store health information about the plurality of cells in the electric battery pack.

16. A computer program product for utilizing a multi-functional wireless module monitoring system (MMS) in an electric battery pack, the computer program product including a non-transitory computer readable storage medium having computer program instructions that when executed by a computer cause the computer to carry out the operations of: monitoring, by the multi-functional wireless MMS, one or more attributes of a plurality of battery cells in the electric battery pack; generating based on the monitored one or more attributes, by the multi-functional wireless MMS, battery sensor data; responsive to the multi-functional wireless MMS operating in a first operational mode, transmitting via a wireless interface, by the multi-functional wireless MMS, a first set of the battery sensor data to a wireless network controller (WNC) of a battery management system (BMS); and responsive to the multi-functional wireless MMS operating in a second operational mode, transmitting via a wired interface, by the multi-functional wireless MMS, a second set of the battery sensor data.

17. The computer program product of statement 16, further comprising computer program instructions that when executed by a computer cause the computer to carry out the operations of transitioning the multi-functional wireless MMS from the first operational mode to the second operational mode by switching from a first protocol to a second protocol for communication via the wireless interface.

18. The computer program product of statements 16 or 17, further comprising computer program instructions that when executed by a computer cause the computer to carry out the operations of responsive to the multi-functional wireless MMS operating in the second operational mode, transmitting via the wireless interface, by the multi-functional wireless MMS, data using the second protocol.

19. The computer program product of any of statements 16-18 further comprising computer program instructions that when executed by a computer cause the computer to carry out the operations of: responsive to the multi-functional wireless MMS operating in the second operational mode: responsive to the multi-functional wireless MMS operating in the second operational mode: receiving from an external wireless device, via the wireless interface and in accordance with the second protocol, by the multi-functional wireless MMS, a request to generate a third set of the battery sensor data based on the one or more attributes; and transmitting to the external wireless device, via the wireless interface and in accordance with the second protocol, by the multi-fimctional wireless MMS, the third set of the battery sensor data.

20. The computer program product of any of statements 16-19 further comprising computer program instructions that when executed by a computer cause the computer to carry out the operations of: responsive to the multi-functional wireless MMS operating in the second operational mode: receiving from an external wireless device, via the wireless interface and in accordance with the second protocol, by the multi-functional wireless MMS, a request to perform a service operation; and in response to receiving the request to perform the service operation, performing, by the multi-functional wireless MMS, the service operation.

One or more embodiments may be described herein with the aid of method steps illustrating the performance of specified fractions and relationships thereof. The boundaries and sequence of these functional building blocks and method steps have been arbitrarily defined herein for convenience of description. Alternate boundaries and sequences can be defined so long as the specified functions and relationships are appropriately performed. Any such alternate boundaries or sequences are thus within the scope and spirit of the claims. Further, the boundaries of these functional building blocks have been arbitrarily defined for convenience of description. Alternate boundaries could be defined as long as the certain significant functions are appropriately performed. Similarly, flow diagram blocks may also have been arbitrarily defined herein to illustrate certain significant functionality.

To the extent used, the flow diagram block boundaries and sequence could have been defined otherwise and still perform the certain significant functionality. Such alternate definitions of both functional building blocks and flow diagram blocks and sequences arc thus within the scope and spirit of the claims. One of average skill in the art will also recognize that the functional building blocks, and other illustrative blocks, modules and components herein, can be implemented as illustrated or by discrete components, application specific integrated circuits, processors executing appropriate software and the like or any combination thereof.

While particular combinations of various functions and features of the one or more embodiments are expressly described herein, other combinations of these features and functions are likewise possible. The present disclosure is not limited by the particular examples disclosed herein and expressly incorporates these other combinations.

What is claimed is:

1. A method for utilizing a multi-functional wireless module monitoring system (MMS) in an electric battery pack, the method comprising:
monitoring, by the multi-functional wireless MMS, one or more attributes of a plurality of battery cells in the electric battery pack;
generating based on the monitored one or more attributes, by the multi-functional wireless MMS, battery sensor data;
responsive to the multi-functional wireless MMS operating in a first operational mode, transmitting via a wireless interface, by the multi-functional wireless MMS, a first set of the battery sensor data to a wireless network controller (WNC) of a battery management system (BMS); and
responsive to the multi-functional wireless MMS operating in a second operational mode, transmitting via a wired interface, by the multi-functional wireless MMS, a second set of the battery sensor data.

2. The method of claim 1, further comprising transitioning the multi-functional wireless MMS from the first operational mode to the second operational mode by switching from a first protocol to a second protocol for communication via the wireless interface.

3. The method of claim 2, further comprising responsive to the multi-functional wireless MMS operating in the second operational mode, transmitting via the wireless interface, by the multi-functional wireless MMS, data using the second protocol.

4. The method of claim 2 further comprising:
responsive to the multi-functional wireless MMS operating in the second operational mode:
receiving from an external wireless device, via the wireless interface and in accordance with the second protocol, by the multi-functional wireless MMS, a request to generate a third set of the battery sensor data based on the one or more attributes; and
transmitting to the external wireless device, via the wireless interface and in accordance with the second protocol, by the multi-functional wireless MMS, the third set of the battery sensor data.

5. The method of claim 2 further comprising:
responsive to the multi-functional wireless MMS operating in the second operational mode:
receiving from an external wireless device, via the wireless interface and in accordance with the second protocol, by the multi-functional wireless MMS, a request to perform a service operation; and
in response to receiving the request to perform the service operation, performing, by the multi-functional wireless MMS, the service operation.

6. The method of claim 1 further comprising using, by the multi-functional wireless MMS, the monitored one or more attributes to generate and store health information about the plurality of cells in the electric battery pack.

7. The method of claim 6 further comprising based on the stored health information about the plurality of cells in the electric battery pack, determining, by the multi-functional wireless MMS, a status of the plurality of cells for second life usage.

8. The method of claim 2, wherein the second protocol comprises a Bluetooth Low Energy (BLE) protocol.

9. The method of claim 1 wherein the multi-functional wireless MMS includes a sensor for sensing current associated with the plurality of battery cells.

10. An apparatus including a processor and memory coupled to the processor, the memory including computer program instructions that when executed by the processor cause the apparatus to carry out the operations of:
monitoring, by the multi-functional wireless MMS, one or more attributes of a plurality of battery cells in the electric battery pack;
generating based on the monitored one or more attributes, by the multi-functional wireless MMS, battery sensor data;
responsive to the multi-functional wireless MMS operating in a first operational mode, transmitting via a wireless interface, by the multi-functional wireless MMS, a first set of the battery sensor data to a wireless network controller (WNC) of a battery management system (BMS); and
responsive to the multi-functional wireless MMS operating in a second operational mode, transmitting via a wired interface, by the multi-functional wireless MMS, a second set of the battery sensor data.

11. The apparatus of claim 10, wherein the memory further includes computer program instructions that when executed by the processor cause the apparatus to carry out the operations of: transitioning the multi-functional wireless MMS from the first operational mode to the second operational mode by switching from a first protocol to a second protocol for communication via the wireless interface.

12. The apparatus of claim 11, wherein the memory further includes computer program instructions that when executed by the processor cause the apparatus to carry out the operations of: responsive to the multi-functional wireless MMS operating in the second operational mode, transmitting via the wireless interface, by the multi-functional wireless MMS, data using the second protocol.

13. The apparatus of claim 11 wherein the memory further includes computer program instructions that when executed by the processor cause the apparatus to carry out the operations of:
responsive to the multi-functional wireless MMS operating in the second operational mode:
receiving from an external wireless device, via the wireless interface and in accordance with the second protocol, by the multi-functional wireless MMS, a request to generate a third set of the battery sensor data based on the one or more attributes; and
transmitting to the external wireless device, via the wireless interface and in accordance with the second protocol, by the multi-functional wireless MMS, the third set of the battery sensor data.

14. The apparatus of claim 11 wherein the memory further includes computer program instructions that when executed by the processor cause the apparatus to carry out the operations of:
responsive to the multi-functional wireless MMS operating in the second operational mode:
receiving from an external wireless device, via the wireless interface and in accordance with the second protocol, by the multi-functional wireless MMS, a request to perform a service operation; and
in response to receiving the request to perform the service operation, performing, by the multi-functional wireless MMS, the service operation.

15. The apparatus of claim 10 wherein the memory further includes computer program instructions that when executed by the processor cause the apparatus to carry out the operations of: using, by the multi-functional wireless MMS, the monitored one or more attributes to generate and store health information about the plurality of cells in the electric battery pack.

16. A computer program product for utilizing a multi-functional wireless module monitoring system (MMS) in an electric battery pack, the computer program product including a non-transitory computer readable storage medium having computer program instructions that when executed by a computer cause the computer to carry out the operations of:
monitoring, by the multi-functional wireless MMS, one or more attributes of a plurality of battery cells in the electric battery pack:
generating based on the monitored one or more attributes, by the multi-functional wireless MMS, battery sensor data;
responsive to the multi-functional wireless MMS operating in a first operational mode, transmitting via a wireless interface, by the multi-functional wireless MMS, a first set of the battery sensor data to a wireless network controller (WNC) of a battery management system (BMS); and
responsive to the multi-functional wireless MMS operating in a second operational mode, transmitting via a wired interface, by the multi-functional wireless MMS, a second set of the battery sensor data.

17. The computer program product of claim 16, further comprising computer program instructions that when executed by a computer cause the computer to carry out the operations of transitioning the multi-functional wireless MMS from the first operational mode to the second operational mode by switching from a first protocol to a second protocol for communication via the wireless interface.

18. The computer program product of claim 17, further comprising computer program instructions that when executed by a computer cause the computer to carry out the operations of responsive to the multi-functional wireless MMS operating in the second operational mode, transmitting via the wireless interface, by the multi-functional wireless MMS, data using the second protocol.

19. The computer program product of claim 17 further comprising computer program instructions that when executed by a computer cause the computer to carry out the operations of:
responsive to the multi-functional wireless MMS operating in the second operational mode:
receiving from an external wireless device, via the wireless interface and in accordance with the second protocol, by the multi-functional wireless MMS, a request to generate a third set of the battery sensor data based on the one or more attributes; and
transmitting to the external wireless device, via the wireless interface and in accordance with the second protocol, by the multi-fimctional wireless MMS, the third set of the battery sensor data.

20. The computer program product of claim 17 further comprising computer program instructions that when executed by a computer cause the computer to carry out the operations of:
responsive to the multi-functional wireless MMS operating in the second operational mode:
receiving from an external wireless device, via the wireless interface and in accordance with the second protocol, by the multi-functional wireless MMS, a request to perform a service operation; and
in response to receiving the request to perform the service operation, performing, by the multi-functional wireless MMS, the service operation.
